(19) United States
(12) Patent Application Publication
(10) Pub. No.: US 2016/0163985 A1
(43) Pub. Date: Jun. 9, 2016

(54) MANUFACTURING METHOD OF ORGANIC LIGHT-EMITTING ELEMENT AND ORGANIC LIGHT-EMITTING ELEMENT

(71) Applicant: JOLED INC., Tokyo (JP)

(72) Inventors: Kazuhiro YOKOTA, Tokyo (JP); Yuuki ABE, Tokyo (JP); Jun HASHIMOTO, Tokyo (JP)

(73) Assignee: JOLED INC., Tokyo (JP)

(21) Appl. No.: 14/962,208

(22) Filed: Dec. 8, 2015

(30) Foreign Application Priority Data
Dec. 9, 2014 (JP) 2014-249000

(51) Int. Cl. H01L 51/00; H01L 51/50; H01L 51/52; H01L 51/56

(52) U.S. Cl. CPC H01L 51/0021; H01L 51/56; H01L 51/5012; H01L 51/5206; H01L 51/5221

(57) ABSTRACT

A method for manufacturing an organic light-emitting element, including: preparing a substrate; forming a light-reflective layer above the substrate, the light-reflective layer containing Al or an Al alloy; forming an alumina layer by oxidizing a part of the light-reflective layer; forming a metal layer on the alumina layer, the metal layer containing a metal having electrical conductivity regardless of whether or not the metal is oxidized; forming an electrically-conductive layer on the metal layer, the electrically-conductive layer containing a light-transmissive oxide; and forming an organic light-emitting layer and a light-transmissive electrode above the electrically-conductive layer.

This application is based on an application No. 2014-249000 filed in Japan, the contents of which are hereby incorporated by reference.

### BACKGROUND OF THE DISCLOSURE

(1) Technical Field

The present disclosure is related to an organic light-emitting element making use of an electric-field light-emission phenomenon occurring with organic material. In particular, the present disclosure is related to a light-reflective electrode included in an organic light-emitting element.

(2) Description of Related Art

An organic light-emitting element is one type of a light-emitting element that makes use of an electric-field light-emission phenomenon occurring with organic material. An organic light-emitting element, when used in a display panel, an illumination device, or the like, needs to achieve both high light-emitting efficiency and low power consumption.

Japanese Patent Application Publication No. 2010-192144 discloses one example of a top-emission-type organic light-emitting element achieving high light-emitting efficiency. In specific, the conventional organic light-emitting element disclosed in Japanese Patent Application Publication No. 2010-192144 includes: an upper electrode; a lower electrode; and an organic light-emitting layer between the upper electrode and the lower electrode. The upper electrode is light-transmissive, whereas the lower electrode is light-reflective. In the conventional organic light-emitting element, a part of the light emitted from the organic light-emitting layer travels directly towards the light-transmissive electrode without travelling towards the light-reflective electrode. Meanwhile, the rest of the light emitted from the organic light-emitting layer travels towards the light-reflective electrode, and then travels to the light-transmissive electrode by being reflected at the light-reflective electrode. This results in interference between light travelling directly to the light-transmissive electrode and light travelling to the light-transmissive electrode after being reflected at the light-reflective electrode. This interference provides the conventional organic light-emitting element with high light emission efficiency. Meanwhile, in the conventional organic light-emitting element, the light-reflective electrode contains, for example, Al or an Al alloy, or Ag or an Ag alloy, which are examples of metals having high light-reflectivity. In particular, Al and Al alloys are widely used in conventional organic light-emitting elements as the material for light-reflective electrodes, owing to their relatively low price.

### SUMMARY OF THE DISCLOSURE

The present disclosure aims to provide a manufacturing method that yields an organic light-emitting element that has high light-emission efficiency and that is drivable with low driving voltage. Further, the present disclosure also aims to provide an organic light-emitting element having such characteristics.

In view of this, one aspect of the present disclosure is a method for manufacturing an organic light-emitting element, including: preparing a substrate; forming a light-reflective layer above the substrate, the light-reflective layer containing Al or an Al alloy; forming an alumina layer by oxidizing a part of the light-reflective layer; forming a metal layer on the alumina layer, the metal layer containing a metal having electrical conductivity regardless of whether or not the metal is oxidized; forming an electrically-conductive layer on the metal layer, the electrically-conductive layer containing a light-transmissive oxide; and forming an organic light-emitting layer and a light-transmissive electrode above the electrically-conductive layer.

An organic light-emitting element manufactured according to this method includes a metal layer between a light-reflective layer and an electrically-conductive layer containing a light-transmissive oxide. Accordingly, the oxygen present in light-transmissive oxide contained in the electrically-conductive layer reacts with the metal contained in the metal layer, and thus does not react with the Al (or Al alloy) in the light-reflective layer. Thus, the Al (or Al alloy) in the light-reflective layer does not undergo oxidization in reaction with the oxygen present in light-transmissive oxide contained in the electrically-conductive layer. This prevents the forming of alumina in the light-reflective electrode, and thus suppresses an increase in driving voltage for driving the organic light-emitting element.

Further, in this method, an alumina layer is formed at a part of the surface of the light-reflective layer by causing the part of the surface of the light-reflective layer to undergo oxidization, before the metal layer is layered on the light-reflective layer. Due to this, each of (i) the boundary between the light-reflective layer and the alumina layer, (ii) the boundary between the alumina layer and the metal layer, and (iii) the boundary between the metal layer and the electrically conductive layer is smooth and makes the layers at both sides thereof clearly distinguishable from one another. In other words, the light-reflective electrode has a clearly separated layer structure. Thus, the light-reflective electrode has high reflectance, which in turn provides the organic light-emitting element including the light-reflective electrode with high light-emission efficiency.

Thus, the present disclosure yields an organic light-emitting element that has high light-emission efficiency and that is drivable with low driving voltage.

### BRIEF DESCRIPTION OF THE DRAWINGS

These and other objects, advantages, and features of the technology pertaining to the present disclosure will become apparent from the following description thereof taken in conjunction with the accompanying drawings, which illustrate at least one specific embodiment of the technology pertaining to the present disclosure.

FIG. 1A is a cross-sectional diagram providing schematic illustration of an organic light-emitting element pertaining to an embodiment of the present disclosure, and FIG. 1B is an enlargement of portion A in FIG. 1A.

FIG. 2 is a flowchart illustrating a method for manufacturing the organic light-emitting element pertaining to the embodiment.

FIG. 3 is a flowchart illustrating a method for manufacturing a light-reflective electrode pertaining to the embodiment.

Each of FIGS. 4A through 4G is a cross-sectional diagram illustrating a procedure in the method for manufacturing the organic light-emitting element pertaining to the embodiment.

Each of FIGS. 5A through 5F is a cross-sectional diagram illustrating a procedure in the method for manufacturing the organic light-emitting element pertaining to the embodiment.

Each of FIGS. 6A and 6B is a cross-sectional diagram illustrating a procedure in the method for manufacturing the organic light-emitting element pertaining to the embodiment.

FIG. 7 is a cross-sectional diagram illustrating an organic display panel pertaining to the embodiment.

FIG. 8 is a diagram illustrating functional blocks of the organic display device pertaining to the embodiment.

FIG. 9 illustrates the light reflectivity of a light-reflective anode in each of a conventional example, a comparative example, and an embodiment pertaining to the present disclosure.

FIG. 10A illustrates light-emission efficiency of blue light, for each of the conventional example, the comparative example, and the embodiment pertaining to the present disclosure, and FIG. 10B illustrates panel driving voltage, for each of the conventional example, the comparative example, and the embodiment.

FIG. 11A is a microscope photograph showing a layer structure of the light-reflective anode in the conventional example, FIG. 11B is a microscope photograph showing a layer structure of the light-reflective anode in the comparative example, and FIG. 11C is a microscope photograph showing a layer structure of the light-reflective anode in the embodiment.

### DESCRIPTION OF EMBODIMENT

### 1. How Present Inventors Arrived at Aspects of Present Disclosure

In the following, description is provided of how the present inventors arrived at various aspects of the present disclosure, before actually describing the aspects of the present disclosure in further detail.

Conventionally, when using an alloy mostly composed of Al as the material of a light-reflective electrode, an electrically-conductive layer containing a light-transmissive oxide (e.g., ITO or IZO), which functions as a protection layer, is layered on the Al alloy layer to increase tolerance of the light-reflective electrode to various manufacturing processes. This provides the light-reflective electrode with high light reflectivity, at the same time as preventing the Al alloy layer from being damaged in subsequent processing such as patterning. However, typically, Al undergoes oxidization easily. Due to this, when layering an electrically-conductive layer containing a light-transmissive oxide on the Al alloy layer, Al in the Al alloy layer undergoes oxidization by reacting with the oxygen present in the oxide contained in the electrically-conductive layer, and thus, an AlOx layer (i.e., an alumina layer) is formed at the boundary between the Al alloy layer and the electrically-conductive layer.

Since alumina is an electrical insulator, the AlOx layer has high electrical resistance, and when the AlOx layer exists between the Al alloy layer and the electrically-conductive layer in the light-reflective electrode, a high driving voltage would be required for driving the organic light-emitting element including the light-reflective electrode.

One measure for preventing the forming of the AlOx layer would be to intentionally include a layer (referred to in the following as an oxidization target layer) that is to undergo oxidization by reacting with the oxygen present in the light-transmissive oxide contained in the electrically-conductive layer, between the Al alloy layer and the electrically-conductive layer. That is, the presence of the oxidization target layer would prevent Al contained in the Al alloy layer from coming into contact with the oxygen present in the light-transmissive oxide contained in the electrically-conductive layer. In the present disclosure, an oxidization target layer contains a metal having electrical conductivity regardless of whether or not the metal is oxidized, such as W or Mo.

Further, the forming of the AlOx layer in the Al alloy layer would be almost completely avoidable, by adopting the above-measure and in addition, performing all procedures from the forming of the Al alloy layer to the forming of the oxidization target layer inside a vacuum. Performing such procedures in a vacuum prevents Al in the Al alloy layer from reacting to oxygen present in the atmosphere and thereby undergoing natural oxidization before the oxidization target layer is formed.

The present inventors conducted an analysis by using a light-reflective electrode formed in the above-described manner. The analysis revealed that the driving voltage required for driving an organic light-emitting element whose the light-reflective electrode was formed as described above was lower than the driving voltage required for driving an organic light-emitting element with a conventional light-reflective electrode not including the oxidization target layer. Meanwhile, the observation also revealed that the reflectance of the light-reflective electrode formed in the above-described manner was lower than the reflectance of the conventional light-reflective electrode not including the oxidization target layer. This is not desirable, since a light-reflective electrode should reflect, with desirable reflectance, light emitted from an organic light-emitting layer. That is, a light-reflective electrode formed by adopting the above measures, which achieves a reduction in driving current but in the meantime has low reflectance, is not desirable.

In view of this, the present inventors conducted further research regarding light-reflective electrodes containing Al, and through such research, have arrived at an organic, light-emitting element that can be driven with low voltage and that includes a light-reflective electrode with high reflectance.

### 2. Aspects of Present Disclosure

One aspect of the present disclosure is a method for manufacturing an organic light-emitting element, including: preparing a substrate; forming a light-reflective layer above the substrate, the light-reflective layer containing Al or an Al alloy; forming an alumina layer by oxidizing a part of the light-reflective layer; forming a metal layer on the alumina layer, the metal layer containing a metal having electrical conductivity regardless of whether or not the metal is oxidized; forming an electrically-conductive layer on the metal layer, the electrically-conductive layer containing a light-transmissive oxide; and forming an organic light-emitting layer and a light-transmissive electrode above the electrically-conductive layer.

An organic light-emitting element manufactured according to this method includes a metal layer between a light-reflective layer and an electrically-conductive layer containing a light-transmissive oxide. Accordingly, the oxygen present in light-transmissive oxide contained in the electrically-conductive layer reacts with the metal contained in the metal layer, and thus does not react with the Al (or Al alloy) in the light-reflective layer. Thus, the Al (or Al alloy) in the light-reflective layer does not undergo oxidization in reaction with the oxygen present in light-transmissive oxide contained in the electrically-conductive layer. This prevents the forming of alumina in the light-reflective electrode, and thus suppresses an increase in driving voltage for driving the organic light-emitting element.

Further, in this method, an alumina layer is formed at a part of the surface of the light-reflective layer by causing the part of the surface of the light-reflective layer to undergo oxidization, before the metal layer is layered on the light-reflective layer. Due to this, each of (i) the boundary between the light-reflective layer and the alumina layer, (ii) the boundary between the alumina layer and the metal layer, and (iii) the boundary between the metal layer and the electrically conductive layer is smooth and makes the layers at both sides thereof clearly distinguishable from one another. In other words, the light-reflective electrode has a clearly separated layer structure. Thus, the light-reflective electrode has high reflectance, which in turn provides the organic light-emitting element including the light-reflective electrode with high light-emission efficiency.

Thus, the method pertaining to one aspect of the present disclosure yields an organic light-emitting element that has high light-emission efficiency and that is drivable with low driving voltage.

In the method pertaining to one aspect of the present disclosure, the metal layer may be formed through sputtering.

According to this, the alumina layer is doped with a small amount of metal. The alumina layer after the doping has lower electrical resistance than the alumina layer before the doping. Due to this, the method pertaining to one aspect of the present disclosure yields an organic light-emitting element drivable with relatively low driving voltage.

In the method pertaining to one aspect of the present disclosure, the metal layer may contain W or Mo.

Both W and Mo have high electrical conductivity. Further, WOx and MoOx also have high electrical conductivity. Layering the electrically-conductive layer on the metal layer results in W or Mo contained in the metal layer undergoing oxidization through reaction with the oxygen present in light-transmissive oxide contained in the electrically-conductive layer. This results in a WOx layer or a MoOx layer being formed at a boundary between the metal layer and the electrically-conductive layer. The WOx layer and the MoOx layer, either one of which may be formed, has electrical conductivity as discussed above, differing from the alumina layer, which is an electrical insulator. Thus, it is preferable to contain W or Mo in the metal layer, a part of which undergoing oxidization in reaction with the oxygen present in light-transmissive oxide contained in the electrically-conductive layer in place of the light-reflective layer.

In the method pertaining to one aspect of the present disclosure, the alumina layer may be formed by performing atmospheric exposure of the substrate having the light-reflective layer formed thereabove,

According to this, the forming of the alumina layer, which is formed by a part of the surface of the light-reflective layer undergoing natural oxidization, on the light-reflective layer can be achieved through a simple procedure.

One aspect of the present disclosure is an organic light-emitting element including, in sequence: a substrate; a light-reflective electrode; an organic light-emitting layer; and a light-transmissive electrode. In the organic light-emitting element, the light-reflective electrode includes: a light-reflective layer containing one of Al and an alloy of Al; an alumina layer; a first electrically-conductive layer; and a second electrically-conductive layer, layered in this order one on top of another with the light-reflective layer closest to the substrate, the first electrically-conductive layer containing a metal oxide, the second electrically-conductive layer containing a light-transmissive oxide.

In the organic light-emitting element pertaining to one aspect of the present disclosure, the alumina layer may contain the metal oxide contained in the first electrically-conductive layer. The alumina layer, when containing a metal, has lower electrical resistance compared to an alumina layer not containing a metal. Thus, the organic light-emitting element pertaining to one aspect of the present disclosure has high light-reflectance at the same time as being drivable with low driving voltage.

In the organic light-emitting element pertaining to one aspect of the present disclosure, the first electrically-conductive layer may contain WOx or MoOx, and the alumina layer may contain W or Mo.

Both WOx and MoOx are metals having high electrical conductivity. Due to this, the organic light-emitting element pertaining to one aspect of the present disclosure is drivable with even lower driving voltage.

One aspect of the present disclosure is a method for manufacturing an organic light-emitting element, the method including: preparing a substrate; forming a first layer above the substrate, the first layer made of Al or an Al alloy; oxidizing a surface portion of the first layer so that the surface portion becomes an alumina portion; depositing a second layer on the surface portion, the second layer made of at least one of W and Mo; depositing a third layer on the second layer, the third layer made of at least one of an oxide of Sn and an oxide of Zn; and forming an organic light-emitting layer and a light-transmissive electrode above the third layer.

In the method pertaining to one aspect of the present disclosure, the oxidizing may be exposure to the atmosphere.

### 3. Structure of Organic Light-Emitting Element

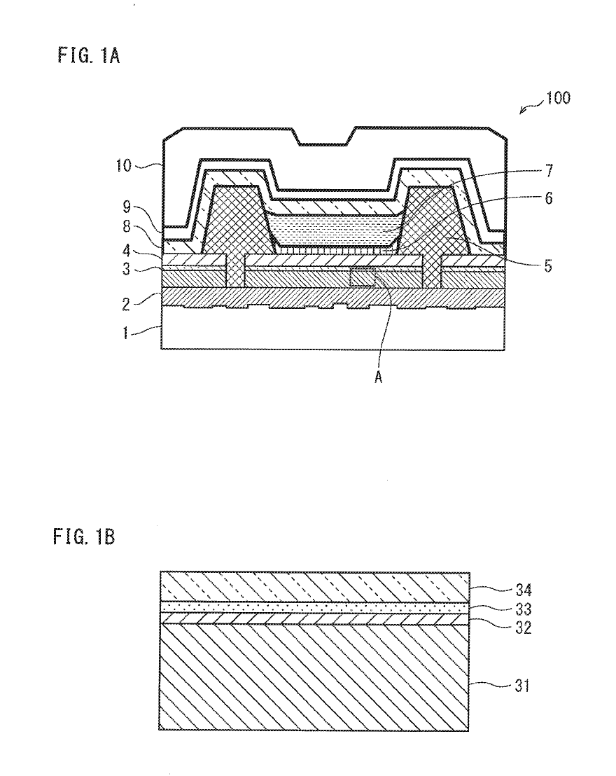

FIG. 1A is a cross-sectional diagram illustrating the structure of an organic light-emitting element pertaining to one embodiment of the present disclosure.

As illustrated in FIG. 1A, the organic light-emitting element pertaining to the present embodiment (i.e., an organic light-emitting element 100) includes: a substrate 1; an insulating layer 2; a light-reflective anode 3; a hole injection layer 4; banks 5; a hole transport layer 6; an organic light-emitting layer 7; an electron transport layer 8; a light-transmissive cathode 9; and a sealing layer 10. The following describes specific examples of the layers.

### (a) Substrate

The substrate 1 is, for example, a TFT substrate composed of an electrically-insulative substrate and TFTs on the electrically-insulative substrate. Examples of material usable for the electrically-insulative substrate include alkali-free glass, soda glass, nonfluorescent glass, phosphate glass, borate glass, quartz, acrylic resin, styrenic resin, polycarbonate resin, epoxy resin, polyethylene, polyester, silicone resin, or alumina.

### (b) Insulating Layer

The insulating layer 2 contains an organic material or an inorganic material. The insulating layer 2 has, for example, the function of planarizing the surface of the substrate 1 (i.e., covering unevennesses of the surface of the substrate 1) and thereby ensuring that each layer above the insulating layer 2 is formed with uniform thickness along the surface of the substrate 1. Examples of organic materials usable for the insulating layer 2 include acrylic resins, polyimide resins, and novolac-type phenolic resins. Examples of inorganic materials usable for the insulating layer 2 include SiO₂ and Si₃N₄.

### (c) Light-Reflective Anode

The light-reflective anode 3 is one example of the light-reflective electrode pertaining to the present disclosure, and forms a matrix on the insulating layer 2. Further, the light-reflective anode 3 is electrically connected to one of the TFT electrodes (undepicted) of the substrate 1. The light-reflective anode 3 has the function of reflecting light received from the organic light-emitting layer 7.

FIG. 1B is an enlargement of part A in FIG. 1A. As illustrated in FIG. 1B, the light-reflective anode 3 includes an aluminum alloy layer 31, an alumina layer 32, a tungsten oxide layer 33, and an electrically-conductive layer 34, layered in this order one on top of another with the aluminum alloy layer 31 closest to the substrate 1. The electrically-conductive layer 34 contains a light-transmissive oxide.

The aluminum alloy layer 31 contains an alloy mostly composed of Al.

The alumina layer 32 is mostly composed of AlOx containing a small amount of metal tungsten. While AlOx is typically an electrical insulator, the AlOx in the alumina layer 32 contains metal tungsten. Thus, the alumina layer 32 has higher electrical conductivity compared to an alumina layer not containing any metal tungsten. The alumina layer 32 may contain WOx.

The tungsten oxide layer 33 is mostly composed of WOx. The tungsten oxide layer 33 may contain metal tungsten. The tungsten oxide layer 33 is electrically conductive. Further, the tungsten oxide layer 33, similar to the alumina layer 32, is extremely thin with a thickness within a range of approximately 1 nm to approximately 5 nm.

The electrically-conductive layer 34 protects the aluminum alloy layer 31 from being damaged in the patterning process. The electrically-conductive layer 34 contains a light-transmissive oxide that allows light generated by the organic light-emitting layer 7 to pass through with desirable light transmittance. The electrically-conductive layer 34 may be made, for example, of ITO, IZO, or the like.

As such, the light-reflective anode 3 includes the alumina layer 32 and the tungsten oxide layer 33, both containing W, sandwiched between the aluminum alloy layer 31 and the electrically-conductive layer 34. Due to this, the light-reflective anode 3 has higher electrical conductivity compared to a conventional light-reflective anode that includes, sandwiched between an aluminum alloy layer and an electrically-conductive layer containing a light-transmissive oxide, an alumina layer that does not contain W and thus is an electrical insulator.

### (d) Hole Injection Layer

The hole injection layer 4 contains an oxide of a transition metal or an oxide of an alloy of a transition metal. The term “transition metal” typically refers to elements belonging to any group between Group 3 and Group 11 in the periodic table. Among such transition metals, oxides of transition metals such as W, Mo, Ni, Ti, V, Cr, Mn, Fe, Co, Nb, and Ta have high hole injectability. In particular, WOx, MoOx, and NiOx have high in-gap states, and thus have higher hole injectability than oxides of other transition metals. Due to this, when utilizing organic light-emitting elements in a display panel, it is typically desirable that WOx, MoOx, or NiOx be used as hole injection layer material.

### (e) Banks

The banks 5 contain an electrically-insulative organic material or an electrically-insulative inorganic material. Examples of organic materials usable for the banks 5 include acrylic resins, polyimide resins, and novolac-type phenolic resins. Examples of inorganic materials usable for the banks 5 include SiO₂ and Si₃N₄. The banks 5 define one sub-pixel. Within the area defined by the banks 5, the hole transport layer 6 and the organic light-emitting layer 7 are layered in this order one on top of the other. Further, the electron transport layer 8, the light-transmissive cathode 9, and the sealing layer 10 are layered above the organic light-emitting layer 7 in this order one on top of another. Each of the electron transport layer 8, the light-transmissive cathode 9, and the sealing layer 10 extends over the area defined by the banks 5, and thus extends continuously over multiple sub-pixels.

### (f) Hole Transport Layer

The hole transport layer 6 is made of, for example, a triazole derivative, an oxadiazole derivative, an imidazole derivative, a polyarylalkane derivative, a pyrazoline derivative, a pyrazolone derivative, a phenylenediamine derivative, an arylamine derivative, an amino-substituted chalcone derivative, an oxazole derivative, a styrylanthracene derivative, a fluorenone derivative, a hydrazone derivative, a stilbene derivative, a porphyrin compound, an aromatic tertiary amine compound and styrylamine compound, a butadiene compound, a polystyrene derivative, a triphenylmethane derivative, or a tetraphenylbenzene derivative, all of which are disclosed in Japanese Patent Application Publication No. H5-163488. For example, the hole transport layer 6 is made of PEDOT:PSS (poly(3,4-ethylenedioxythiophene) doped with polystyrene sulfonate) or a derivative (copolymer, etc.,) of PEDOT:PSS. Materials particularly desirable as the material of the hole transport layer 6 include a porphyrin compound, and an aromatic tertiary amine compound and styrylamine compound. The hole transport layer 6 has the function of transporting, to the organic light-emitting layer 7, the holes that the hole injection layer 4 injects into the hole transport layer 6.

### (g) Organic Light-emitting Layer

For example, the organic light-emitting layer 7 is made of F8BT(Poly(9,9-di-n-octy/fluorene-alt-benzothiadiazole)), which is an organic high polymer. The organic light-emitting layer 7 emits light by making use of an electric-field light-emission phenomenon occurring with organic material.

Alternatively, materials other than F8BT may be used for the organic light-emitting layer 7. For example, it is preferable that the organic light-emitting layer 7 be made of a fluorescent material such as an oxinoid compound, perylene compound, coumarin compound, azacoumarin compound, oxazole compound, oxadiazole compound, perinone compound, pyrrolo-pyrrole compound, naphthalene compound, anthracene compound, fluorene compound, fluoranthene compound, tetracene compound, pyrene compound, coronene compound, quinolone compound, azaquinolone compound, pyrazoline derivative, pyrazolone derivative, rhodamine compound, chrysene compound, phenanthrene compound, cyclopentadiene compound, stilbene compound, diphenylquinone compound, styryl compound, butadiene compound, dicyanomethylene pyran compound, dicyanomethylene thiopyran compound, fluorescein compound, pyrylium compound, thiapyrylium compound, selenapyrylium compound, telluropyrylium compound, aromatic aldadiene compound, oligophenylene compound, thioxanthene compound, cyanine compound, acridine compound, metal complex of a 8-hydroxyquinoline compound, metal complex of a 2-bipyridine compound, complex of a Schiff base and a group III metal, metal complex of oxine, rare earth metal complex, etc., as disclosed in Japanese Patent Application Publication No. H5-163488.

### (h) Electron Transport Layer

The electron transport layer 8 is made of, for example, barium, phthalocyanine, lithium fluoride, or a mixture of such materials. The electron transport layer 8 has the function of transporting, to the organic light-emitting layer 7, electrons that the light-transmissive cathode 9 injects into the electron transport layer 8,

Alternatively, the electron transport layer 8 may be made of, for example, a nitro-substituted fluorenone derivative, a thiopyran dioxide derivative, a diphenylquinone derivative, a perylene tetracarboxyl derivative, an anthraquinodimethane derivative, a fluoronylidene methane derivative, an anthrone derivative, an oxadiazole derivative, a perinone derivative, or a quinolone complex derivative, as disclosed in Japanese Patent Application Publication No. H5-163488.

### (i) Light-Transmissive Cathode

The light-transmissive cathode 9 contains electrically-conductive material allowing light that the organic light-emitting layer 7 emits to pass therethrough with a desirable level of transmittance. Examples of electrically-conductive material usable for the light-transmissive cathode 9 include ITO and IZO.

### (j) Sealing Layer

The sealing layer 10 has the function of preventing layers such as the organic light-emitting layer 7 from being exposed to moisture and/or air. Further, it is desirable that the sealing layer 10 allow light that the organic light-emitting layer 7 emits to pass therethrough with a desirable level of transmittance. For example, the sealing layer 10 may contain SiN or SiON.

### 4. Method for Manufacturing Organic Light-Emitting Element

The following describes a method of manufacturing the organic light-emitting element pertaining to the embodiment.

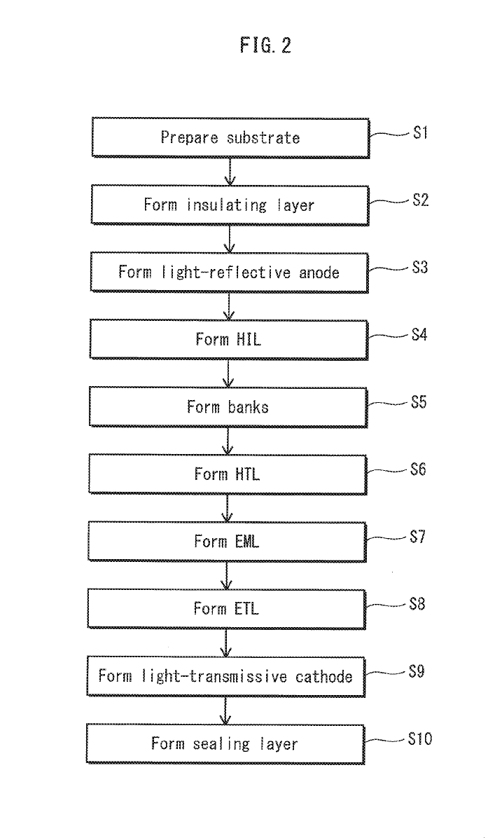

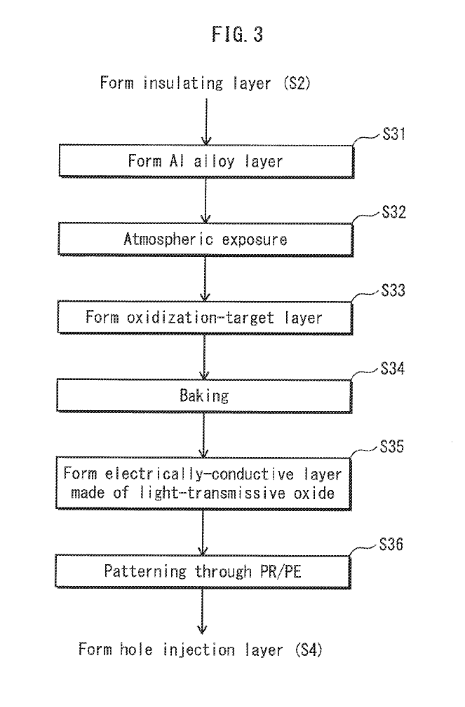

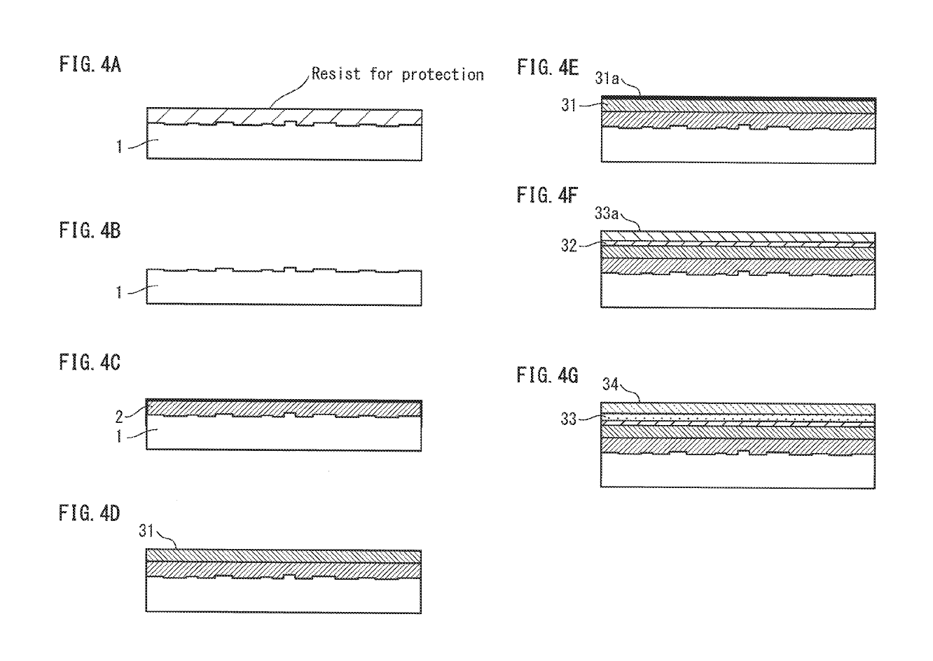

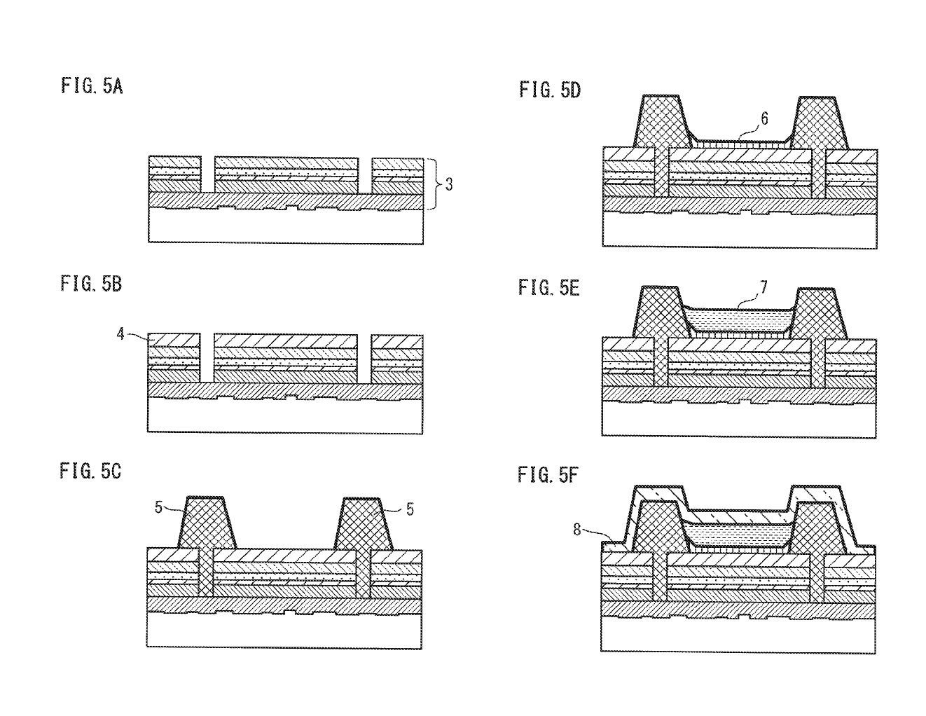

Each of FIGS. 2 and 3 is a flowchart illustrating the method for manufacturing the organic light-emitting element. Further, FIGS. 4A through 4G, FIGS. 5A through 5F, and FIGS. 6A and 6B each are a cross-sectional diagram illustrating a procedure in the method for manufacturing the organic light-emitting element.

In Step S1, first, the substrate 1 is prepared as illustrated in FIG. 4A. At this point, an upper surface of the substrate 1 is protected with resist for protection. Then, the resist for protection covering the substrate 1 is removed, as illustrated in FIG. 4B.

In Step S2, organic resin material is spin-coated onto the substrate 1, and patterning is performed through photoresist photoetching (PR/PE) to form the insulating layer 2, as illustrated in FIG. 4C. The insulating layer 2 is formed to have a thickness of 4 μm, and so that the surface thereof is substantially planar.

In Step S3, forming of a light-reflective anode is performed. FIG. 3 is a flowchart illustrating the forming of the light-reflective anode in detail. The following describes Step S3 in detail, with reference to FIG. 3.

In Step S31, vapor deposition or sputtering is performed to form the aluminum alloy layer 31, which contains an alloy mostly composed of aluminum, on the insulating layer 2, as illustrated in FIG. 4D. The aluminum alloy layer 31 is formed to have a thickness of 150 nm, for example.

In Step S32, the substrate with the aluminum alloy layer 31 formed thereon is removed from a vacuum chamber and is exposed to the atmosphere. This causes a part of the surface of the aluminum alloy layer 31 to undergo oxidization, and thus, an alumina layer 31a is formed on the surface of the aluminum alloy layer 31, as illustrated in FIG. 4E. The alumina layer 31a is formed to have a thickness within a range of approximately 1 nm to approximately 5 nm.

In Step S33, an oxidization target layer 33a is formed on the alumina layer 31a. In this example, metal tungsten is used as the material of the oxidization target layer 33a. In specific, as illustrated in FIG. 4F, the oxidization target layer 33a is formed by forming a film of metal tungsten on the alumina layer 31a through sputtering. The oxidization target layer 33a is formed to have a thickness of 5 nm, for example. Through the forming of the oxidization target layer 33a, the alumina layer 31a is doped with a small amount of metal tungsten. As a result, the alumina layer 31a, which is an electrical insulator, becomes the alumina layer 32, which has higher electrical conductivity than the alumina layer 31a for being doped with metal tungsten.

In Step S34, baking of the substrate with the oxidization target layer 33a formed thereon is performed to sinter the surface of the oxidization target layer 33a.

In Step S35, vapor deposition or sputtering is performed to form the electrically-conductive layer 34, which contains a light-transmissive oxide (ITO, IZO or the like), on the oxidization target layer 33a as a protective film. The electrically-conductive layer 34 is formed to have a thickness of 10 nm, for example. Here, through forming the electrically-conductive layer 34 on the oxidization target layer 33a, metal tungsten in the oxidization target layer 33a undergoes oxidization in reaction with the oxygen contained in the electrically-conductive layer 34. Due to this, the oxidization target layer 33a undergoes a change in characteristics and becomes the tungsten oxide layer 33.

In Step S36, patterning into a matrix is performed through photoresist photoetching, as illustrated in FIG. 5A.

Through such procedures, the light-reflective anode 3 is formed. In the following, description is continued referring to FIG. 2 once again.

In Step S4, the hole injection layer (HIL) 4 is formed on the light-reflective anode 3, as illustrated in FIG. 5B. The hole injection layer 4 is formed by first performing sputtering to form a layer made of an oxide of a transition metal, and then patterning the layer so formed through phororesist photoetching. The hole injection layer 4 is formed to have a thickness of 40 nm, for example.

In Step S5, the banks 5 are formed on the hole injection layer 4, as illustrated in FIG. 5C. Here, the banks are formed on areas of the hole injection layer 4 corresponding to boundaries separating an area where one organic light-emitting element is to be formed from an area where another organic light-emitting element is to be formed. In specific, the banks 5 are formed by first depositing a layer of bank material to cover the surface of the hole injection layer 4 and, exposed surfaces of the insulating layer 2, and then removing a part of the layer so formed through photoresist photoetching. The banks 5 are formed to have a thickness of 1 μm, for example. Further, the banks 5 may form a line hank structure, where the banks form stripes extending in one direction among the column direction and the row direction, or may form a pixel bank structure where the banks form a lattice extending in both the column direction and the row direction.

In Step S6, the hole transport layer (HTL) 6 is formed by applying ink containing hole transport layer material to an inside of the recess defined by the banks 5 as illustrated in FIG. 5D, and drying the ink. The hole transport layer 6 is formed to have a thickness of 20 nm, for example,

In Step S7, the organic light-emitting layer (EML) 7 is formed by applying ink containing organic light-emitting element material to an inside of the recess defined by the banks 5 by using an inkjet method as illustrated in FIG. 5E, drying the ink, under an atmospheric temperature of 25 degrees Celsius and under reduced pressure, and performing baking The organic light-emitting layer 7 is formed to have a thickness within a range of 5 nm to 90 nm. Note that the application of the ink to the inside of the recess defined by the banks 5 may be performed through methods other than an inkjet method. For example, the application of ink may be performed through a dispenser method, nozzle-coating, spin-coating, intaglio printing, or relief printing.

In Step S8, vapor deposition is performed to form the electron transport layer (ETL) 8 to cover the banks 5 and the organic light-emitting layer 7, as illustrated in FIG. 5F. The electron transport layer 8 is formed to have a thickness of 20 nm.

In Step S9, the light-transmissive cathode 9 is formed above the electron transport layer 8, as illustrated in FIG. 6A. The light-transmissive cathode 9 and the light-reflective anode 3 have opposite polarities and thus compose an electrode pair. In specific, plasma vapor deposition of light-transmissive material is performed to form the light-transmissive cathode 9 above the electron transport layer 8. The light-transmissive cathode 9 is formed to have a thickness of 100 nm.

In Step S1.0, the sealing layer 10 is formed above the light-transmissive cathode 9 through performing CVD, as illustrated in FIG. 6B. The sealing layer 10 is formed to have a thickness of 1 μm.

Through such procedures, the organic light-emitting element pertaining to the embodiment, which is a top-emission-type organic light-emitting element, is manufactured.

### 5. Organic Display Panel

The following describes an organic display panel 110, which is one example of implementation of the organic light-emitting element 100 pertaining to the embodiment.

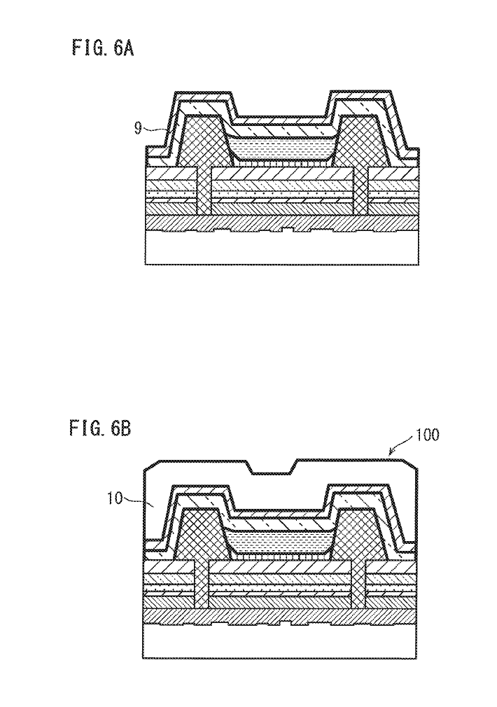

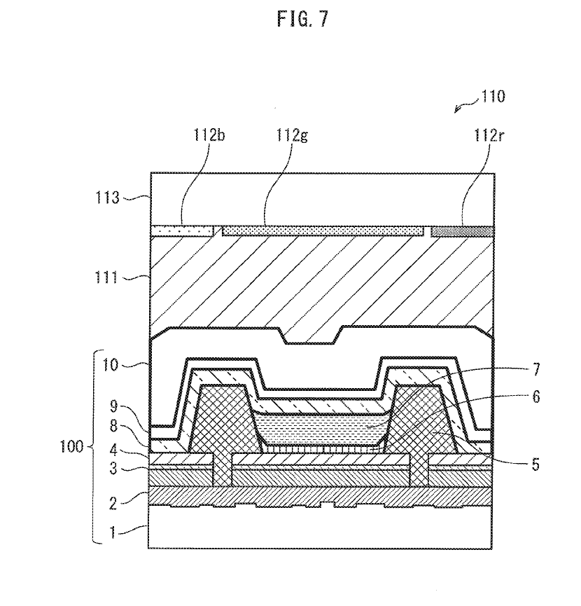

FIG. 7 is a cross-sectional diagram schematically illustrating the pixel structure of the organic display panel 110.

The organic display panel 110 includes: a plurality of the organic light-emitting elements 100; sealing material 111; color filters 112b, 112g, 112r; and a substrate 113.

### (a) Organic Light-Emitting Element

In the organic display panel 110, the organic light-emitting elements 100 are disposed in a line structure or a matrix structure. One organic light-emitting element 100 corresponds to one sub-pixel, of one of the colors R, G, and B. As already discussed above, each organic light-emitting element 100 is a top-emission-type organic light-emitting element. Further, as already discussed above, each sub-pixel includes the substrate 1, and the following layers disposed above the substrate 1: the insulating layer 2; the light-reflective anode 3; the hole injection layer 4; the banks 5; the hole transport layer 6; the organic light-emitting layer 7; the electron transport layer 8; the light-transmissive cathode 9; and the sealing layer 10.

### (b) Sealing Material

The sealing material 111 adheres the organic light-emitting elements 100 to the substrate 113 having the color filters 112b, the color filters 112g, and the color filters 112r formed thereon. The sealing material 111 also has the function of preventing the layers of the organic light-emitting elements 100 from being exposed to moisture and/or air. The sealing material 111 may be made, for example, of a resin-based adhesive.

### (c) Color Filters

The color filters (i.e., the color filters 112b, the color filters 112g, and the color filters 112r) have the function of providing the light emitted from the organic light-emitting elements 100 with a desired chromaticity.

### 6. Organic Display Device

The following describes an organic display device that is one example of implementation of the organic light-emitting element 100 pertaining to the embodiment.

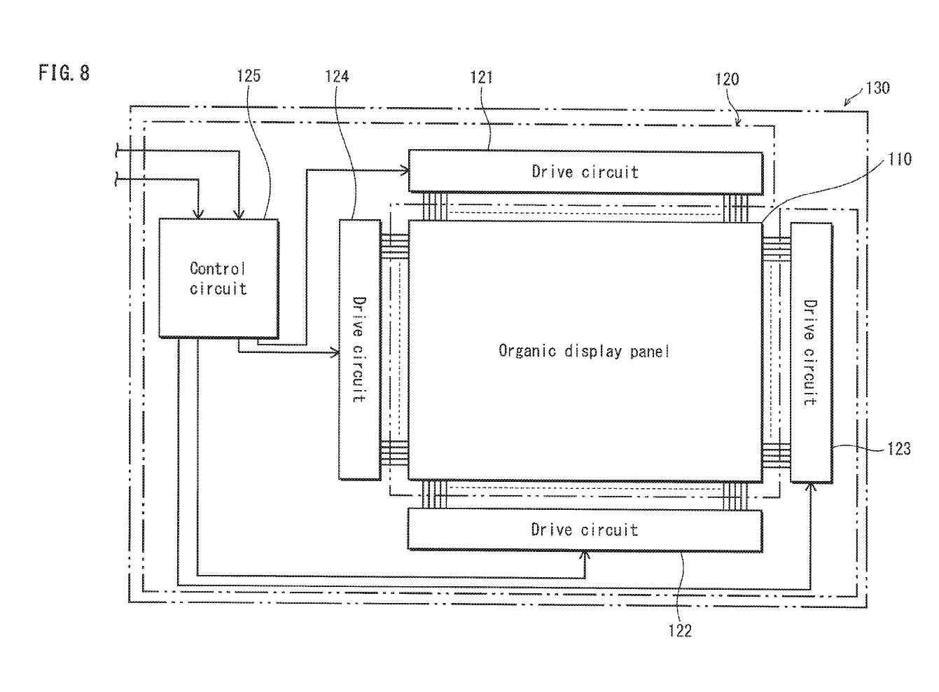

FIG. 8 illustrates functional blocks of the organic display device pertaining to the embodiment. The organic display device pertaining to the embodiment (organic display device 130) includes the organic display panel 110, and a drive/control unit 120 that is electrically connected to the organic display panel 110. As already discussed above, the organic display panel 110 has the pixel structure illustrated in FIG. 7. The drive-control unit 120 includes four drive circuits (namely drive circuits 121, 122, 123, 124) and a control circuit 125 that controls the operation of the drive circuits 121 through 124.

### 7. Observation

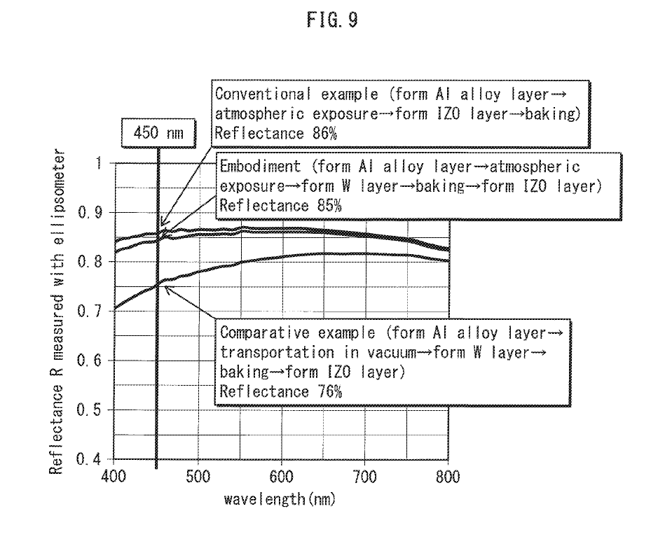

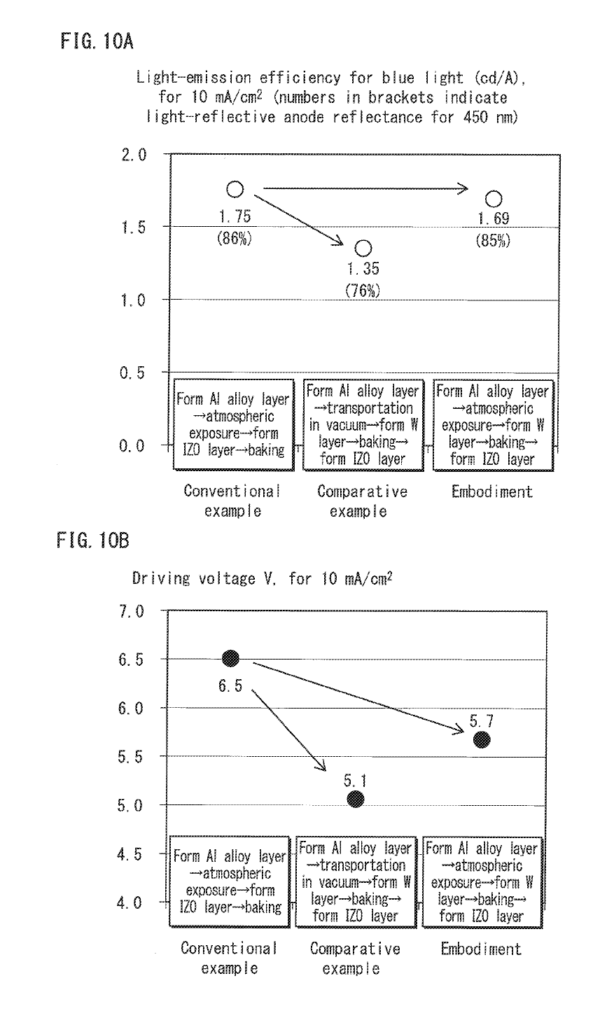

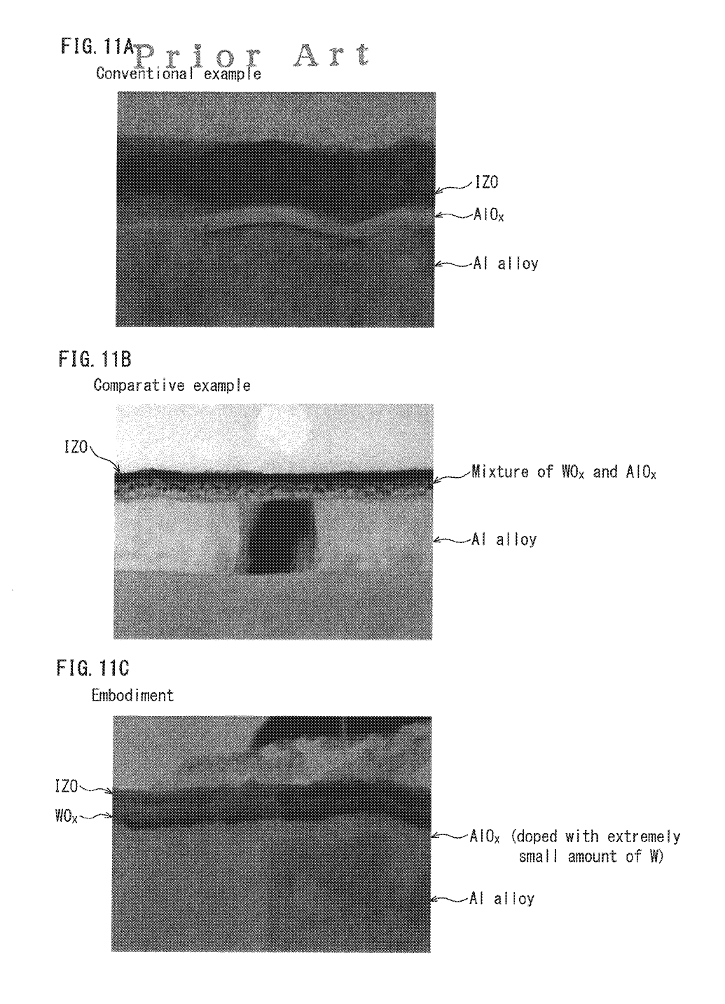

The following compares the light-reflective anode pertaining to the embodiment with a light-reflective anode pertaining to a conventional example and a light-reflective anode pertaining to a comparative example, with reference to FIG. 9, FIGS. 10A and 10B, and FIGS. 11A through 11C.

The light-reflective anode pertaining to the conventional example was formed by (a) forming an aluminum alloy layer, (b) performing atmospheric exposure, (c) forming an IZO layer, which is one example of an electrically-conductive layer containing a light-transmissive oxide, and then (d) performing baking.

The light-reflective anode pertaining to the comparative example was formed by (a) forming an aluminum alloy layer, (b) performing transportation in a vacuum, (c) forming a metal tungsten layer, (d) performing baking, and then (e) fanning an IZO layer, which is one example of an electrically-conductive layer containing a light-transmissive oxide.

The light-reflective anode pertaining to the embodiment was formed by (a) forming an aluminum alloy layer, (b) performing atmospheric exposure, (c) forming a metal tungsten layer, (d) performing baking, and then (e) forming an IZO layer, which is one example of an electrically-conductive layer containing a light-transmissive oxide.

FIG. 9 is a diagram illustrating a relation between a wavelength of light and light reflectance measured by using a spectroscopic ellipsometer, for each of the light-reflective anode pertaining to the conventional example, the light-reflective anode pertaining to the comparative example, and the light-reflective anode pertaining to the embodiment. As illustrated in FIG. 9, the light-reflective anode pertaining to the embodiment and the light-reflective anode pertaining to the conventional example exhibited almost the same level of reflectance at all wavelengths. Meanwhile, the light-reflective anode pertaining to the comparative example had lower reflectance than the light-reflective anode pertaining to the conventional example. In particular, the reflectance of the light-reflective anode pertaining to the comparative example was such that the shorter the wavelength, the greater the difference between the reflectance of the light-reflective anode pertaining to the comparative example and the reflectance of the light-reflective anode pertaining to the conventional example.

In specific, when focusing on wavelength 450 nm corresponding to blue light, the light-reflective anode pertaining to the conventional example had a reflectance of 85% and the light-reflective anode pertaining to the embodiment had a reflectance of 84%. Thus, the light-reflective anode pertaining to the embodiment and the light-reflective anode pertaining to the conventional example exhibited almost the same level of reflectance. Meanwhile, the light-reflective anode pertaining to the comparative example had a reflectance of 76% at wavelength 450 nm, and thus, the light-reflective anode pertaining to the comparative example had considerably lower reflectance than the light-reflective anode pertaining to the embodiment and the light-reflective anode pertaining to the conventional example.

This means that reflectance of the light-reflective electrode varies according to which one of vacuum transportation (as with the comparative example) and atmospheric exposure (as with the present embodiment) is performed between the forming of the aluminum alloy layer and the forming of the metal tungsten layer.

FIG. 10A illustrates light-emission efficiency, in particular for blue light, of organic light-emitting panels each made by using a different one of the light-reflective anode pertaining to the conventional example, the light-reflective anode pertaining to the comparative example, and the light-reflective anode pertaining to the embodiment. Further, FIG. 10B illustrates the driving voltages of such organic light-emitting panels.

In specific, FIG. 10A illustrates the light-emission efficiency for blue light, for current density 10 mA/cm². The percentage values in brackets illustrated in FIG. 10A each indicate the reflectance of a corresponding light-reflective anode, discussed above with reference to FIG. 9. When focusing on blue light, the organic light-emitting panel pertaining to the embodiment had a light-emission efficiency of 1.69 cd/A, and the organic light-emitting panel pertaining to the conventional example had a light-emission efficiency of 1.75 cd/A. Thus, the light-emitting panel pertaining to the embodiment and the organic light-emitting panel pertaining to the conventional example had almost the same light-emission efficiency for blue light. Meanwhile, the light-emitting panel pertaining to the comparative example had a light-emission efficiency of 1.35 cd/A for blue light, and thus, the light-emitting panel pertaining to the comparative example had considerably lower light-emission efficiency than the light-emitting panel pertaining to the embodiment and the light-emitting panel pertaining to the conventional example.

Further, FIG. 10B illustrates the driving voltages of the respective organic light-emitting panels, for current density 10 mA/cm². FIG. 10B illustrates that the organic light-emitting panel pertaining to the conventional example required the highest driving voltage of 6.5 V, whereas the organic light-emitting panel pertaining to the comparative example and the organic light-emitting panel pertaining to the embodiment required lower driving voltages. In specific, the organic light-emitting panel pertaining to the comparative example required a driving voltage of 5.1 V, and the organic light-emitting panel pertaining to the embodiment required a driving voltage of 5.7 V.

As such, compared to the organic light-emitting panel pertaining to the conventional example, which does not include an oxidization target layer, the organic light-emitting panel pertaining to the embodiment achieved a reduction in driving voltage while having a light-emission efficiency of the same, desirable level. Meanwhile, compared to the organic light-emitting panel pertaining to the conventional example, the organic light-emitting panel pertaining to the comparative example did achieve a reduction in driving voltage but in the meantime, had lower light-emission efficiency. Here, it should be noted that light-emission efficiency for blue light is typically lower than light-emission efficiency for green and red light. Accordingly, an attempt to improve light-emission efficiency for blue light with the organic light-emitting panel pertaining to the comparative example would eventually result in an increase in driving voltage.

Further, in the following, a consideration is made of the factors giving rise to the above-described differences occurring depending upon which one of vacuum transportation (as with the comparative example) and atmospheric exposure (as with the present embodiment) is performed between the forming of the aluminum alloy layer and the forming of the metal tungsten layer, with reference to the microscope photographs shown in FIGS. 11A through 11C.

FIG. 11A is a microscope photograph of a cross-section of the light-reflective anode pertaining to the conventional example. As can be seen from FIG. 11A, the light-reflective anode pertaining to the conventional example is composed of an aluminum alloy layer, an alumina (AlOx) layer, and an IZO layer layered in this order one on top of another with the aluminum alloy layer closest to the substrate. Further, FIG. 11A shows that the respective layers of the light-reflective anode pertaining to the conventional example can be clearly distinguished from one another at the boundaries therebetween. FIG. 11A also shows that each of the layers have a high level of density and uniformity. The light-reflective anode pertaining to the conventional example achieves high reflectance for the boundaries between the layers being clear as discussed above. Meanwhile, the light-reflective anode pertaining to the conventional example requires high driving voltage due to a dense layer of alumina, which is an electrical insulator, existing between the aluminum alloy layer and the IZO layer.

FIG. 11B is a microscope photograph of a cross-section of the light-reflective anode pertaining to the comparative example. As can be seen from FIG. 11B, the light-reflective anode pertaining to the comparative example includes an intermediate layer between an aluminum alloy layer and an IZO layer. Further, FIG. 11B shows that the aluminum alloy layer and the intermediate layer cannot be clearly distinguished from one another at the boundary therebetween. This is because the intermediate layer, which is made of a mixture of WOx, metal tungsten (W), and alumina (AlOx), is formed due to metal tungsten being embedded directly into the aluminum alloy layer. Further, WOx in the intermediate layer has been generated by metal tungsten undergoing oxidization through reaction with the oxygen in the IZO layer. Further, AlOx in the intermediate layer has been generated by the aluminum in the aluminum alloy layer undergoing oxidization through reaction with the oxygen in the WOx. The light-reflective anode pertaining to the comparative example has relatively low reflectance for the aluminum alloy layer causing diffuse reflection, due to the boundaries between layers not being clear as a result of the presence of the intermediate layer. Meanwhile, the light-reflective anode pertaining to the comparative example requires lower driving voltage than the light-reflective anode pertaining to the conventional example for including the intermediate layer, which is a mixture of alumina being an electrical insulator and WOx being an electrical conductor.

FIG. 11C is a microscope photograph of a cross-section of the light-reflective anode pertaining to the embodiment. As can be seen from FIG. 11C, the light-reflective anode pertaining to the embodiment is composed of an aluminum alloy layer, an alumina (AlOx) layer, a WOx layer, and an IZO layer layered in this order one on top of another with the aluminum alloy layer closest to the substrate. Further, FIG. 11C shows that the respective layers of the light-reflective anode pertaining to the embodiment can be clearly distinguished from one another at the boundaries therebetween. FIG. 11C also shows that the aluminum alloy layer in the light-reflective anode pertaining to the embodiment has a smooth surface, unlike the aluminum alloy layer in the light-reflective anode pertaining to the comparative example. In the light-reflective anode pertaining to the embodiment, the alumina layer is formed on the aluminum alloy layer before the forming of the tungsten layer, due to the surface of the aluminum alloy layer being caused to undergo oxidization. The smooth surface of the aluminum alloy layer is formed by this alumina layer functioning as a protection layer preventing metal tungsten from being embedded directly into the aluminum alloy layer and thus preventing the forming of an intermediate layer as formed in the light-reflective anode in the comparative example The light-reflective anode pertaining to the embodiment achieves high reflectance for having a smooth light-reflecting surface and for the boundaries between the layers being clear as discussed above. Further, the light-reflective anode pertaining to the embodiment differs from the light-reflective anode pertaining to the conventional example for metal tungsten being embedded in the alumina layer. This results in alumina, which is an electrical insulator, being doped with a small amount of metal tungsten, and thus being provided with electrical conductivity. As a result, the light-reflective anode pertaining to the embodiment requires lower driving voltage than the light-reflective anode pertaining to the conventional example.

As such, the organic light-emitting element pertaining to the present embodiment has high light-emission efficiency and is drivable with low driving voltage. Further, the manufacturing method pertaining to the present embodiment yields an organic light-emitting element that has higher light-emission efficiency and is drivable with lower driving voltage, compared to the conventional example and the comparative example.

### 8. Modifications

Up to this point, description has been provided on an organic light-emitting element pertaining to one aspect of the present disclosure and a method for manufacturing the organic light-emitting element pertaining to one aspect of the present disclosure, based on one embodiment. However, needless to say, no limitations whatsoever are intended by the embodiment, and the technology pertaining to the present disclosure should be construed as including, for example, the modifications discussed in the following as well as other possible modifications.

(1) In the embodiment, the oxidization target layer is made of W. However, the oxidization target layer may be made of a material other than W, one example of which is Mo. Further, the oxidization target layer may be made of a material other than W or Mo, provided that the material remains electrically-conductive even after undergoing oxidization due to reaction with the oxygen contained in the electrically-conductive layer containing a light-transmissive oxide.

(2) In the embodiment, the light-reflective layer of the light-reflective anode 3 is made of an aluminum alloy. However, the light-reflective layer of the light-reflective anode 3 may be made of a material other than an aluminum alloy, one example of which is aluminum.

(3) In the embodiment, description is provided assuming that the lower electrode (light-reflective electrode) is an anode and the upper electrode (light-transmissive electrode) is a cathode. Alternatively, the lower electrode may be a cathode and the upper electrode may be an anode.

(4) A modification may be made of including one or more functional layers other than the functional layers described in the embodiments. One example of such a functional layer is an electron transport layer.

(5) In the embodiment, examples are described where the organic light-emitting element pertaining to one aspect of the present disclosure is used in a display panel and a display device. In addition, the organic light-emitting element pertaining to one aspect of the present disclosure may also be used in an illumination device.

(6) Any combination of the embodiment and the modifications shall be construed as being within the spirit and the scope of the present disclosure.

The organic light-emitting element pertaining to one aspect of the present disclosure is usable, for example, in an organic display panel such as an organic EL display panel, in an organic display device such as an organic EL display, and in an organic light-emitting device such as an organic EL illumination device.

Although the technology pertaining to the present disclosure has been fully described by way of examples with reference to the accompanying drawings, it is to be noted that various changes and modifications will be apparent to those skilled in the art. Therefore, unless such changes and modifications depart from the scope of the present disclosure, they should be construed as being included therein.

1. A method for manufacturing an organic light-emitting element, the method comprising:
preparing a substrate;
forming a light-reflective layer above the substrate, the light-reflective layer containing Al or an Al alloy;
forming an alumina layer by oxidizing a part of the light-reflective layer;
forming a metal layer on the alumina layer, the metal layer containing a metal having electrical conductivity regardless of whether or not the metal is oxidized;
forming an electrically-conductive layer on the metal layer, the electrically-conductive layer containing a light-transmissive oxide; and
forming an organic light-emitting layer and a light-transmissive electrode above the electrically-conductive layer.

2. The method of claim 1, wherein
the metal layer is formed through sputtering.

3. The method of claim 1, wherein
the metal layer contains W or Mo.

4. The method of claim 1, wherein
the alumina layer is formed by performing atmospheric exposure of the substrate having the light-reflective layer formed thereabove.

5. An organic light-emitting element comprising, in sequence:
a substrate;
a light-reflective electrode;
an organic light-emitting layer; and
a light-transmissive electrode, wherein
the light-reflective electrode includes: a light-reflective layer containing one of Al and an alloy of Al; an alumina layer; a first electrically-conductive layer; and a second electrically-conductive layer, layered in this order one on top of another with the light-reflective layer closest to the substrate, the first electrically-conductive layer containing a metal oxide, the second electrically-conductive layer containing a light-transmissive oxide.

6. The organic light-emitting element of claim 5, wherein
the first electrically-conductive layer contains WOx or MoOx, and
the alumina layer contains W or Mo.

7. A method for manufacturing an organic light-emitting element, the method comprising:
preparing a substrate;
forming a first layer above the substrate, the first layer made of Al or an Al alloy;
oxidizing a surface portion of the first layer so that the surface portion becomes an alumina portion;
depositing a second layer on the surface portion, the second layer made of at least one of W and Mo;
depositing a third layer on the second layer, the third layer made of at least one of an oxide of Sn and an oxide of Zn; and
forming an organic light-emitting layer and a light-transmissive electrode above the third layer.

8. The method of claim 7, wherein
the oxidizing comprises exposure to the atmosphere.
